(19) United States
(12) Patent Application Publication
(10) Pub. No.: US 2026/0089923 A1
(43) Pub. Date: Mar. 26, 2026

(54) MEMORY DEVICE AND MANUFACTURING METHOD THEREOF

(71) Applicant: NANYA TECHNOLOGY CORPORATION, New Taipei City (TW)

(72) Inventor: Ying-Cheng CHUANG, New Taipei City (TW)

(21) Appl. No.: 18/895,340

(22) Filed: Sep. 24, 2024

(51) Int. Cl. H10B 12/00

(52) U.S. Cl. CPC H10B 12/34; H10B 12/053

(57) ABSTRACT

A method of forming a memory device includes forming a trench in a substrate, forming a first dielectric layer lining the trench, forming a first conductive layer into the trench, etching back the first conductive layer, resulting in a native oxide layer being formed over the first conductive layer, performing an etching process to remove the native oxide layer to expose the first conductive layer and to trim a portion of the first dielectric layer exposed by the first conductive layer, and forming a second conductive layer into the trench and in contact with the first conductive layer.

### BACKGROUND

### Field of Disclosure

The present disclosure relates to a memory device and a manufacturing method thereof.

### Description of Related Art

A dual work function word line structure is a kind of common word line structure in s memory device. The dual work function word line structure includes two conductive layers with different work functions, and the source/drain regions are formed at the sides of the conductive layer with lower work function to reduce the gate-induced drain leakage (GIDL) in the memory device. On the other hands, short write-back (SWB) is a critical criteria of the memory device, and it means that a write back operation is operated to be able to reach a certain amount of the charges in the memory device to read the data in a certain short duration. GIDL and SWB should be balanced, such that GIDL of the memory device is not too high, and the memory device meets the SWB criteria at the same time.

### SUMMARY

Some embodiments of the present disclosure provide a method of forming a memory device includes forming a trench in a substrate, forming a first dielectric layer lining the trench, forming a first conductive layer into the trench, etching back the first conductive layer, resulting in a native oxide layer being formed over the first conductive layer, performing an etching process to remove the native oxide layer to expose the first conductive layer and to trim a portion of the first dielectric layer exposed by the first conductive layer, and forming a second conductive layer into the trench and in contact with the first conductive layer.

In some embodiments, the second conductive layer is wider than the first conductive layer.

In some embodiments, a thickness of the first dielectric layer protruding from the first conductive layer is less than the first dielectric layer covered by the first conductive layer after the etching process is complete.

In some embodiments, the method further includes etching back the second conductive layer, and forming a second dielectric layer lining the trench after forming the second conductive layer, wherein the second dielectric layer is in contact with the second conductive layer.

In some embodiments, the method further includes forming a capping layer into the trench after etching back the second dielectric layer.

In some embodiments, the first dielectric layer and the second dielectric layer form a gate dielectric layer, and a thickness of the gate dielectric layer lining a sidewall of the second conductive layer is less than a thickness of the gate dielectric layer lining a sidewall of the capping layer.

In some embodiments, the first dielectric layer and the second dielectric layer form a gate dielectric layer, and a thickness of the gate dielectric layer lining a sidewall of the second conductive layer is less than a thickness of the gate dielectric layer lining a sidewall of the first conductive layer.

In some embodiments, the first dielectric layer and the second dielectric layer are made of a same mater In some embodiments, a work function value of the second conductive layer is lower than a work function value of the first conductive layer.

In some embodiments, the first conductive layer is made of metal nitride.

Some embodiments of the present disclosure provide a memory device including a substrate, a word line structure and a gate dielectric layer. The word line structure is embedded in the substrate and includes a first conductive layer, a second conductive layer over the first conductive layer, and a capping layer over the second conductive layer. The gate dielectric layer lines the word line structure and includes a first portion lining a sidewall of the first conductive layer, a second portion lining a sidewall of the second conductive layer, and a third portion lining a sidewall of the capping layer, in which a thickness of the second portion of the gate dielectric layer is less than a thickness of the first portion of the gate dielectric layer.

In some embodiments, the thickness of the second portion of the gate dielectric layer is less than a thickness of the third portion of the gate dielectric layer.

In some embodiments, a thickness of the third portion of the gate dielectric layer is greater than the thickness of the first portion of the gate dielectric layer.

In some embodiments, the gate dielectric layer further comprises a fourth portion between the second conductive layer and the capping layer.

In some embodiments, a thickness of the fourth portion of the gate dielectric layer is less than a thickness of the third portion of the gate dielectric layer.

In some embodiments, the first conductive layer is in contact with the second conductive layer.

In some embodiments, a work function value of the second conductive layer is lower than a work function value of the first conductive layer.

In some embodiments, the first conductive layer is made of metal nitride.

In some embodiments, the second conductive layer is wider than the first conductive layer.

In some embodiments, the first portion of the gate dielectric layer is in contact with a bottom surface of the second conductive layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a circuit diagram of a memory device in some embodiments of the present disclosure.

FIGS. 2-11 illustrate cross-section views of a manufacturing method of a memory device in some embodiments of the present disclosure.

### DETAILED DESCRIPTION

Some embodiments of the present disclosure are related to a memory device, and the word line of the memory device in the present disclosure can be controlled without coupling to reduce the operation time of the memory device. Moreover, the thickness of the date dielectric layer in the present disclosure can be designed to balance the gate-induced drain leakage (GIDL) and the short write-back (SWB) of the memory device.

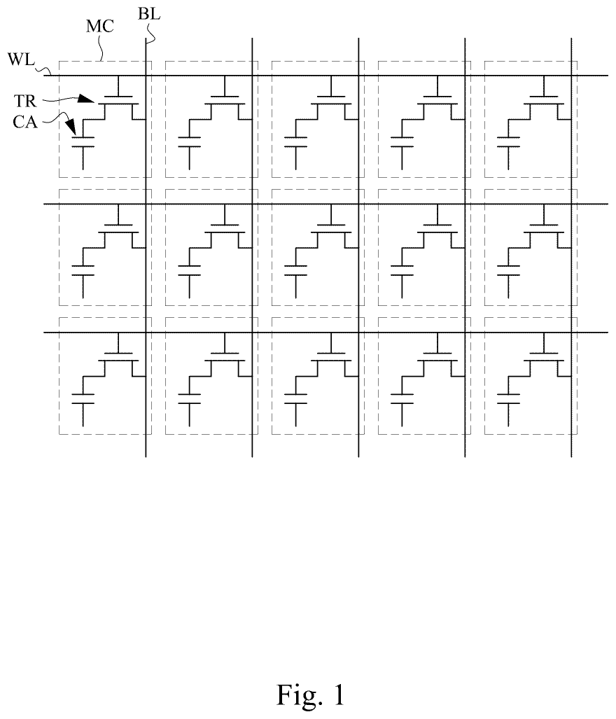

FIG. 1 illustrates a circuit diagram of a memory device in some embodiments of the present disclosure. Referring to FIG. 1, the memory device (e.g., dynamic random access memory, DRAM) may include a plurality of memory cells MC. A typical DRAM memory cell MC incorporates a capacitor CA and a transistor TR in which the capacitor CA temporarily store data based on the charged state of the capacitor CA. A bit line BL is electrically connected to a source/drain region of the transistor TR, and a word line structure WL is electrically connected to a gate region of the transistor TR. The capacitor CA is electrically connected to the other source/drain region of the respective transistor TR. The word line structure WL in the present disclosure is a dual work function word line structure. The later discussion will emphasize the manufacturing process of the transistor TR and the word line structure WL, and the manufacturing method of the bit line BL and the capacitor CA will not be mentioned.

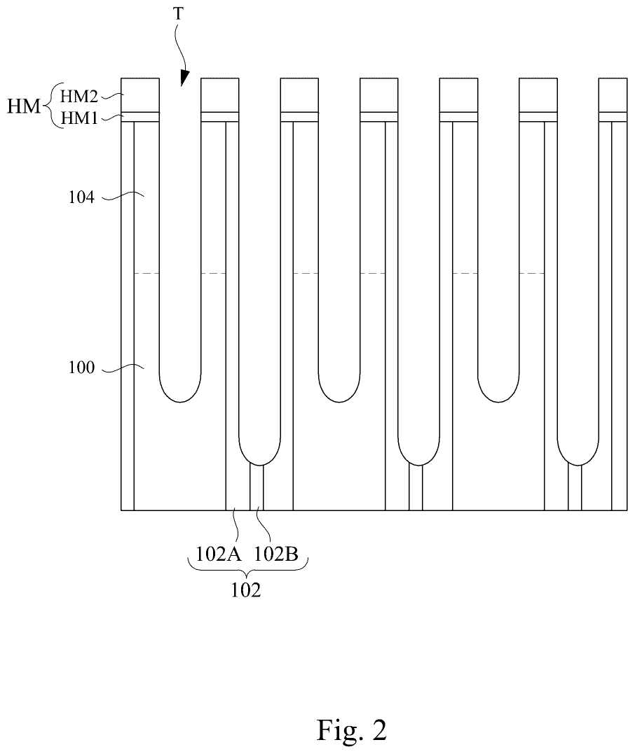

FIGS. 2-11 illustrate cross-section views of a manufacturing method of a memory device in some embodiments of the present disclosure. Referring to FIG. 2, a substrate 100 is provided, and isolation structures 102 are formed in the substrate 100. The substrate 100 includes doped regions 104 at the upper portion of the substrate 100. The substrate 100 and the doped regions 104 have different conductivity type. For example, if the substrate 100 is an n-type substrate, then the doped regions 104 are p-type regions. If the substrate 100 is a p-type substrate, then the doped regions 104 are n-type regions. The p-type substrate and the p-type region include the p-type dopants, such as boron, gallium or aluminum. The n-type substrate and the n-type region include the n-type dopant, such as phosphorus, arsenic, or antimony. The doped regions 104 serve as the source/drain regions in the transistor TR in FIG. 1, and the substrate 100 serves as the channel region in the transistor TR in FIG. 1. In some embodiments, the substrate 100 may be made of semiconductor material, such as silicon. In some embodiments, the isolation structures 102 may be made of dielectric material, such as silicon oxide, silicon nitride, or combinations thereof. For example, each of the isolation structures 102 may include a first portion 102A of the isolation structure made of silicon oxide and a second portion 102B of the isolation structure made of silicon nitride.

Subsequently, a hard mask layer HM is formed over the substrate 100, and trenches T are formed in the substrate 100 by etching the substrate 100 through the hard mask layer HM. The bottom of the trench T is lower than the bottom of the doped region 104. In some embodiments, the trenches T are further formed in the isolation structures 102, and the bottom of the trench T in the isolation structure 102 is lower than the bottom of the trench T in the substrate 100.

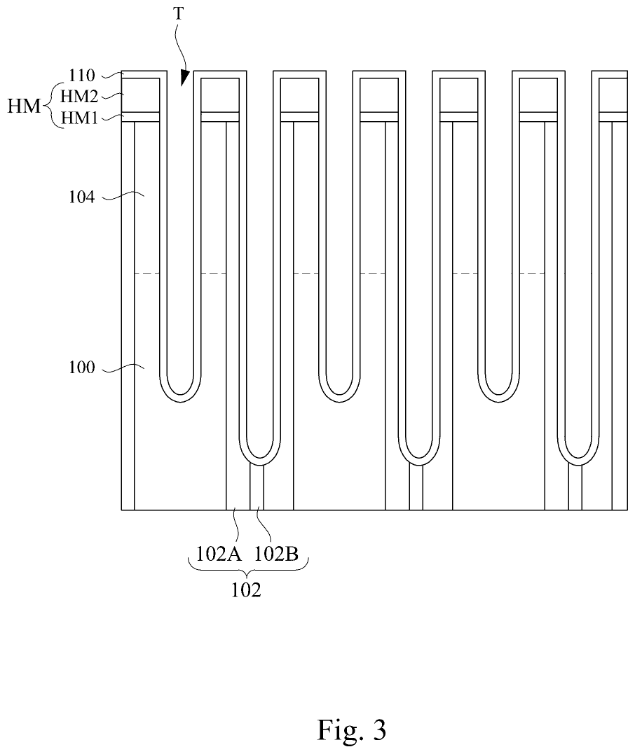

Referring to FIG. 3, a dielectric layer 110 is formed lining the trenches T in the substrate 100 and the trenches T in the isolation structures 102. The dielectric layer 110 is further along the top surface and the sidewall of the hard mask layer HM. In some embodiments, the dielectric layer 110 may be formed by atomic layer deposition (ALD), in situ steam generation (ISSG) or combinations thereof. The In-Situ Steam Generation (ISSG), for example, can be performed with water steam or a combined gas of hydrogen (H₂) and oxygen (O₂), so as to oxidize surface of the substrate 100 to form the dielectric layer 110. In some embodiment, the dielectric layer 110 is made of silicon oxide. In some embodiments, the thickness of the dielectric layer 110 is about 3 nm to 7 nm. In some embodiments, the thickness of the dielectric layer 110 formed by ALD or the thickness of the dielectric layer 110 formed by ISSG may be adjusted to balance the GIDL and the SWB of the memory device. Specifically, the gate-induced drain leakage (GIDL) is the tunneling-based leakage currents caused where the gate overlaps the drain. On the other hands, short write-back (SWB) is a critical criteria of the memory device, and it means that a write back operation is operated to be able to reach a certain amount of the charges in the memory device to read the data in a certain short duration. Generally, SWB is achieved at the higher GIDL. However, excessive GIDL adversely affects the memory device. Therefore, GIDL and SWB should be balanced, such that GIDL of the memory device is not too high, and the memory device meets the SWB criteria at the same time.

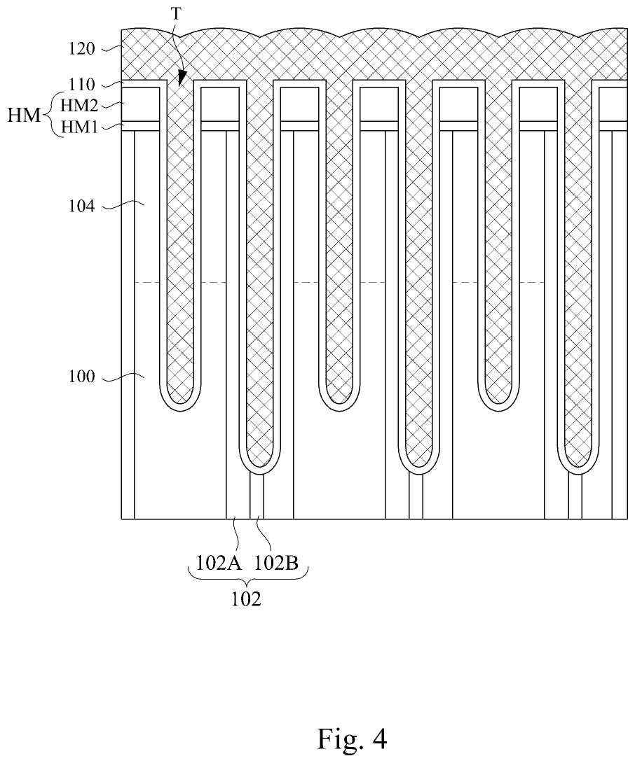

Referring to FIG. 4, a conductive layer 120 is formed overfilling the trenches T. That is, the conductive layer 120 is not only formed into the trenches T, but also covers the hard mask layer HM and the dielectric layer 110. The conductive layer 120 is made of a conductive material. In some embodiments, the conductive layer 120 is made of metal nitride, such as titanium nitride (TiN).

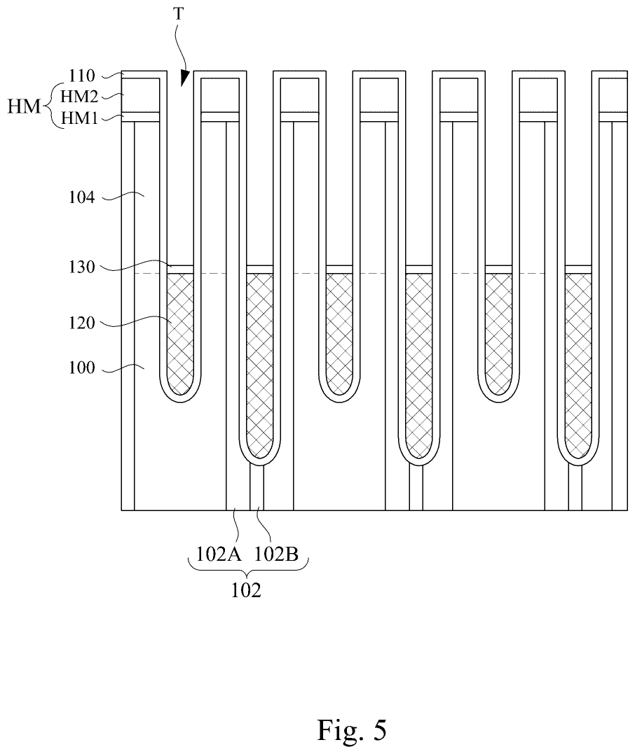

Referring to FIG. 5, the conductive layer 120 is etched back to lower the top surface of the conductive layer 120. In some embodiments, the top surface of the first word line layer 120 is not higher than the bottom of the doped region 104. In some embodiments, etching back the conductive layer 120 may oxidize the top surface of the conductive layer, thereby resulting in a native oxide layer 130 being formed over the conductive layer 120. The native oxide layer 130 may affect the subsequent manufacturing process of the memory device. After the conductive layer 120 is etched back, a portion of the dielectric layer 110 is exposed.

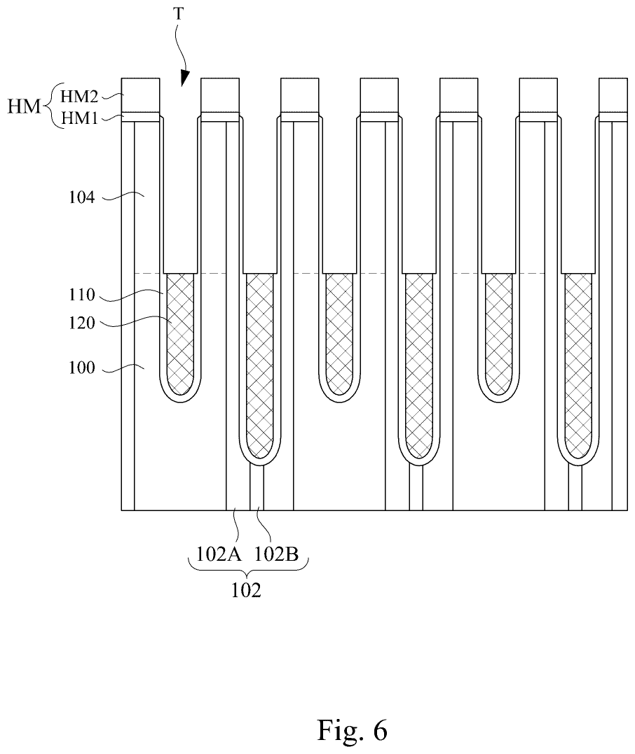

Referring to FIG. 6, an etching process is performed on the conductive layer 120 to remove the native oxide layer 130 to expose the conductive layer 120 and to trim a portion of the dielectric layer 110 exposed by the first conductive layer 120. In some embodiments, trimming a portion of the dielectric layer 110 exposed by the first conductive layer may include laterally etching the dielectric layer 110 during removing the native oxide layer 130. This will results in that a thickness of the dielectric layer 110 protruding from the conductive layer 120 is less than a thickness of the dielectric layer 110 covered by the conductive layer 120. The amount of the dielectric layer 110 being trimmed is adjusted to balance the GIDL and SWB. In some embodiments, the thickness of the dielectric layer 110 after being laterally etched is about 1 nm to 5 nm.

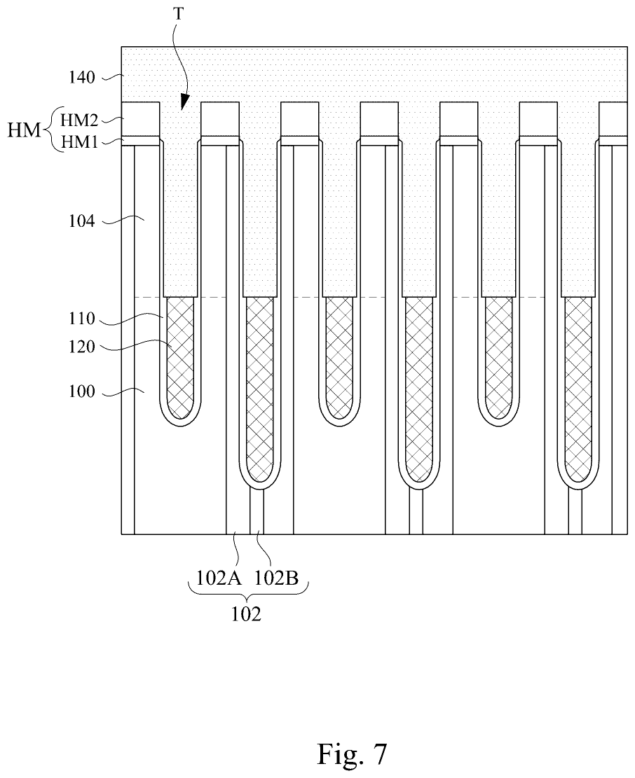

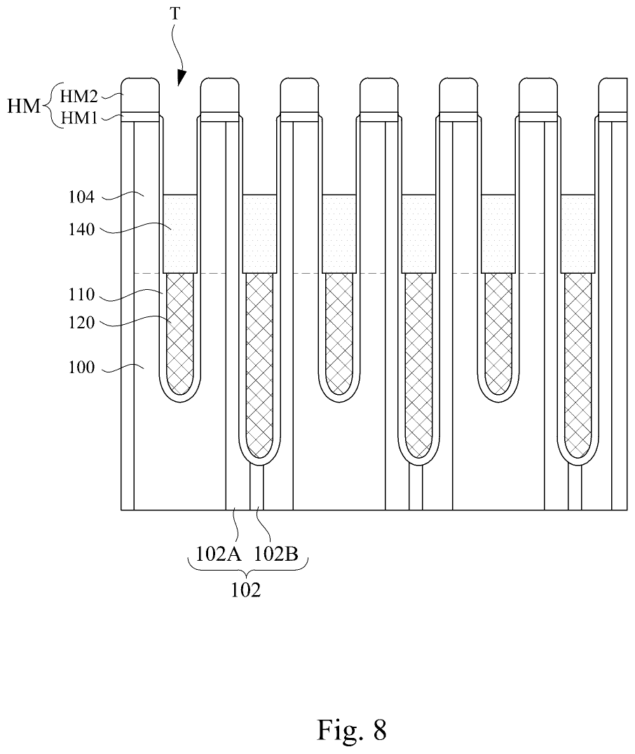

Referring to FIG. 7, a conductive layer 140 is formed into the trenches T and in contact with the conductive layer 120. Subsequently, referring to FIG. 8, an etching back process is performed on the conductive layer 140 to lower the top surface of the conductive layer 140. The conductive layer 140 is wider than the conductive layer 120 since the dielectric layer 110 in contact with the conductive layer 140 is trimmed. Therefore, the dielectric layer 110 is in contact with the bottom surface of the conductive layer 140. The conductive layer 140 and the conductive layer 120 are made of different materials. In some embodiments, the work function value of the conductive layer 140 is lower than the work function value of the conductive layer 120. The material of the conductive layer 120 and the conductive layer 140 are chosen properly, so the material of the conductive layer 120 and the conductive layer 140 will not diffuse into each other. In some embodiments, the conductive layer 140 is made of polysilicon. Since the native oxide layer 130 is removed in the previous stage, it is ensured that the conductive layer 140 is in contact with the conductive layer 120 and will be beneficial for the operation of the word line in the memory device in the present disclosure.

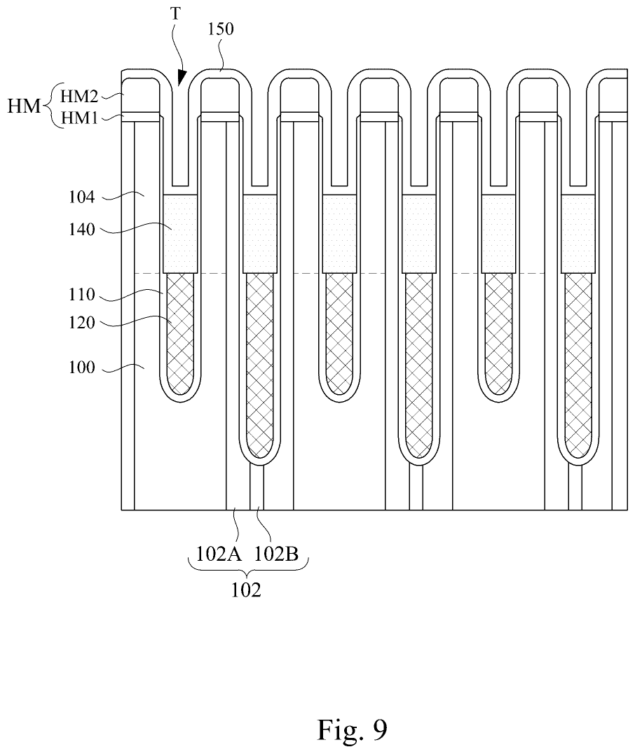

Referring to FIG. 9, a dielectric layer 150 is formed lining the trenches T and in contact with the conductive layer 140. The dielectric layer 150 is further along the top surface and the sidewall of the hard mask layer HM. In some embodiments, the dielectric layer 150 and the dielectric layer 110 are made of same materials, such as silicon oxide. In some embodiments, the thickness of the dielectric layer 150 is about 1.5 nm to 5 nm.

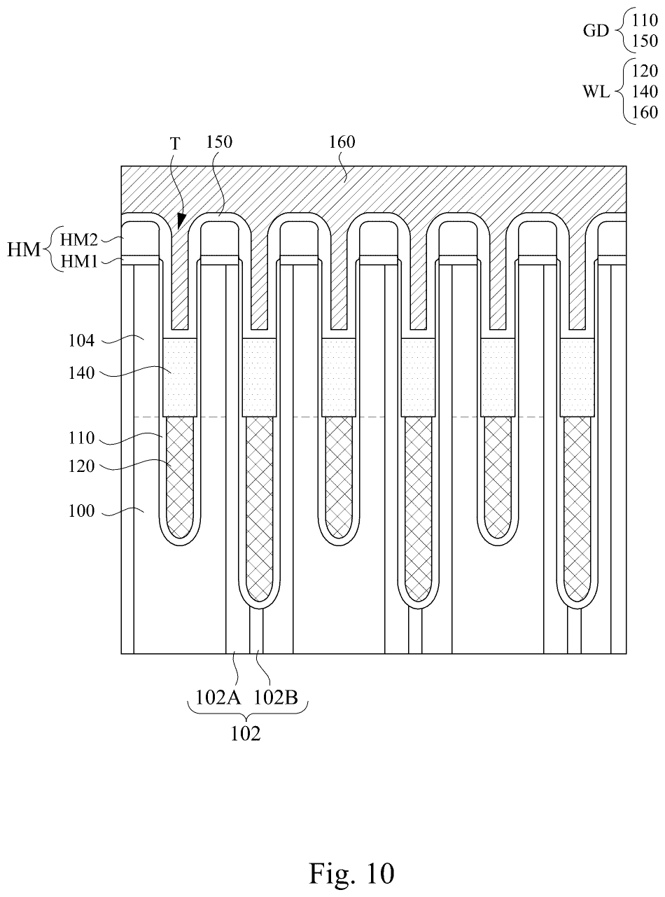

Referring to FIG. 10, a capping layer 160 is formed in the trenches T and over the conductive layer 140 and the dielectric layer 150. The dielectric layer 150 is along the sidewall and the bottom of the capping layer 160, and a portion of the dielectric layer 150 is between the conductive layer 140 and the capping layer 160. The dielectric layer 150 is further in contact with the dielectric layer 110. In some embodiments, the capping layer 160 is made of dielectric material, and the material of the capping layer 160 is different from the material of the dielectric layer 110 and the dielectric layer 150. In some embodiments, the capping layer 160 is made of silicon nitride. In some embodiments, each conductive layer 120 and its corresponding conductive layer 140 and capping layer 160 can be referred to as a word line structure WL in FIG. 1. The dielectric layer 110 and its corresponding dielectric layer 150 can be referred to as a gate dielectric layer GD, and the gate dielectric layer GD serves as the gate dielectric layer of the transistor TR in FIG. 1.

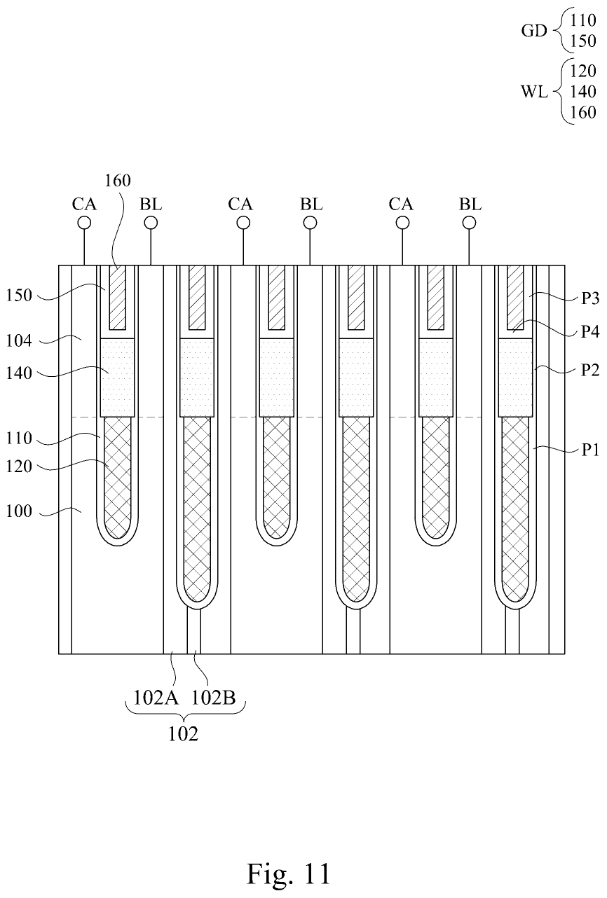

Referring to FIG. 11, a planarization process, such as CMP, is performed on the capping layer 160 until the doped regions 104 of the substrate 100 are exposed. During the planarization process, the hard mask layer HM may also be removed. Afterwards, a bit line BL and a capacitor CA may be formed electrically connected to the doped regions 104.

The resulting memory device is illustrated in FIG. 11. The memory device includes a substrate 100, a word line structure WL, and a gate dielectric layer GD. The word line structure WL is embedded in the substrate 100 and includes a conductive layer 120, a conductive layer 140 and a capping layer 160. The conductive layer 140 is over the conductive layer 120. The capping layer is over the conductive layer 140.

The conductive layer 140 is in contact with the conductive layer 120 since a cleaning process is performed in the present disclosure. The direct contact between the conductive layer 140 and the conductive layer 120 can simplify the operation of the memory structure in the present disclosure. For example, the conductive layer 140 is electrically connected to the conductive layer 120, so the conductive layer 140 and the conductive layer 120 can be controlled without coupling. Specifically, the material of the conductive layer 120 and the conductive layer 140 are chosen properly, so the material of the conductive layer 120 and the conductive layer 140 will not diffuse into each other. Therefore, there is no need to form an additional layer between the conductive layer 120 and the conductive layer 140 to avoid the diffusion between the conductive layer 120 and the conductive layer 140. The conductive layer 140 and the conductive layer 120 of the word line structure WL can be controlled without coupling, and the operation time of the word line structure WL in the present disclosure may decrease accordingly.

The gate dielectric layer GD includes a dielectric layer 110 and a dielectric layer 150. The gate dielectric layer GD is between the substrate 100 and the word line structure WL. The gate dielectric layer GD lines the word line structure WL and includes a first portion P1 lining a sidewall of the conductive layer 120, a second portion P2 lining a sidewall of the conductive layer 140, a third portion P3 lining a sidewall of the capping layer 160, and a fourth portion P4 between the conductive layer 140 and the capping layer 160. The first portion P1 of the gate dielectric layer GD is further in contact with a bottom surface of the conductive layer 140. The manufacturing process of the dielectric layer 110 and the dielectric layer 150 leads to the difference of the thickness among different portions of the gate dielectric layer GD. Specifically, the gate dielectric layer GD is formed by forming the dielectric layer 110 (in FIG. 3), trimming the dielectric layer 110 protruding from the conductive layer 120 (in FIG. 6), and forming the dielectric layer 150 in contact with the dielectric layer 110 and the conductive layer 140 (in FIG. 9). Therefore, the thickness of the second portion P2 of the gate dielectric layer GD (including the trimmed dielectric layer 110) is less than the thickness of the first portion P1 of the gate dielectric layer GD (including the dielectric layer 110 not being trimmed) and the thickness of the third portion P3 of the gate dielectric layer GD (including the combination of the trimmed dielectric layer 110 and the dielectric layer 150). The thickness of the fourth portion P4 of the gate dielectric layer GD (including the dielectric layer 150) is less than the thickness of the third portion P3 of the gate dielectric layer GD (including the combination of the trimmed dielectric layer 110 and the dielectric layer 150). In some embodiments, the thickness of the third portion P3 of the gate dielectric layer GD (including the combination of the trimmed dielectric layer 110 and the dielectric layer 150) is greater than the thickness of the first portion P1 of the gate dielectric layer GD (including the dielectric layer 110 not being trimmed). In some embodiments, the thickness of the fourth portion P4 of the gate dielectric layer GD (including the dielectric layer 150) may be greater than the thickness of the second portion P2 of the gate dielectric layer GD (including the trimmed dielectric layer 110). Specifically, the different thicknesses of different portions of the gate dielectric layer GD may be adjusted to balance the GIDL and SWB of the memory device. For example, since there is no additional dielectric layer formed after laterally etching the dielectric layer 110 and prior to forming the conductive layer 140, the thickness of the second portion P2 of the gate dielectric layer GD can be well-controlled only by adjusting the etching amount of the dielectric layer 110 in FIG. 6. Such configuration will result in a physical contact between the conductive layer 140 and the conductive layer 120 of the word line structure WL, and thus there is no coupling between the conductive layer 140 and the conductive layer 120 of the word line structure WL during the operation of the word line structure WL. The adjustment of the second portion P2 of the gate dielectric layer GD does not take the process of manufacturing the dielectric layer formed between the conductive layer 140 and the conductive layer 120 into consideration. In some embodiments, the dielectric layer 110 and the dielectric layer 150 are made of same materials, and thus the first portion P1, the second portion P2, the third portion and the fourth portion of the gate dielectric layer GD are made of the same materials.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming a memory device, comprising:
forming a trench in a substrate;
forming a first dielectric layer lining the trench;
forming a first conductive layer into the trench;
etching back the first conductive layer, resulting in a native oxide layer being formed over the first conductive layer;
performing an etching process to remove the native oxide layer to expose the first conductive layer and to trim a portion of the first dielectric layer exposed by the first conductive layer; and
forming a second conductive layer into the trench and in contact with the first conductive layer.

2. The method of claim 1, wherein the second conductive layer is wider than the first conductive layer.

3. The method of claim 1, wherein a thickness of the first dielectric layer protruding from the first conductive layer is less than the first dielectric layer covered by the first conductive layer after the etching process is complete.

4. The method of claim 1, further comprising:
etching back the second conductive layer; and
forming a second dielectric layer lining the trench after forming the second conductive layer, wherein the second dielectric layer is in contact with the second conductive layer.

5. The method of claim 4, further comprising:
forming a capping layer into the trench after etching back the second dielectric layer.

6. The method of claim 5, wherein the first dielectric layer and the second dielectric layer form a gate dielectric layer, and a thickness of the gate dielectric layer lining a sidewall of the second conductive layer is less than a thickness of the gate dielectric layer lining a sidewall of the capping layer.

7. The method of claim 5, wherein the first dielectric layer and the second dielectric layer form a gate dielectric layer, and a thickness of the gate dielectric layer lining a sidewall of the second conductive layer is less than a thickness of the gate dielectric layer lining a sidewall of the first conductive layer.

8. The method of claim 5, wherein the first dielectric layer and the second dielectric layer are made of a same material.

9. The method of claim 1, wherein a work function value of the second conductive layer is lower than a work function value of the first conductive layer.

10. The method of claim 1, wherein the first conductive layer is made of metal nitride.

11. A memory device, comprising:
a substrate;
a word line structure embedded in the substrate and comprising:
a first conductive layer;
a second conductive layer over the first conductive layer; and
a capping layer over the second conductive layer; and
a gate dielectric layer lining the word line structure and comprising:
a first portion lining a sidewall of the first conductive layer;
a second portion lining a sidewall of the second conductive layer; and
a third portion lining a sidewall of the capping layer, wherein a thickness of the second portion of the gate dielectric layer is less than a thickness of the first portion of the gate dielectric layer.

12. The memory device of claim 11, wherein the thickness of the second portion of the gate dielectric layer is less than a thickness of the third portion of the gate dielectric layer.

13. The memory device of claim 11, wherein a thickness of the third portion of the gate dielectric layer is greater than the thickness of the first portion of the gate dielectric layer.

14. The memory device of claim 11, wherein the gate dielectric layer further comprises a fourth portion between the second conductive layer and the capping layer.

15. The memory device of claim 14, wherein a thickness of the fourth portion of the gate dielectric layer is less than a thickness of the third portion of the gate dielectric layer.

16. The memory device of claim 11, wherein the first conductive layer is in contact with the second conductive layer.

17. The memory device of claim 11, wherein a work function value of the second conductive layer is lower than a work function value of the first conductive layer.

18. The memory device of claim 11, wherein the first conductive layer is made of metal nitride.

19. The memory device of claim 11, wherein the second conductive layer is wider than the first conductive layer.

20. The memory device of claim 11, wherein the first portion of the gate dielectric layer is in contact with a bottom surface of the second conductive layer.
